(19) United States
(12) Patent Application Publication
(10) Pub. No.: US 2026/0258550 A1
(43) Pub. Date: Sep. 3, 2026

(54) PULSE ALD SEQUENCE FOR LOW FLUORINE NUCLEATION LAYER DEPOSITION

(71) Applicant: Lam Research Corporation, Fremont, CA (US)

(72) Inventors: Xiaolan Ba, Fremont, CA (US); Zizhuo Zhang, San Jose, CA (US); Juwen Gao, San Jose, CA (US); Sanjay Gopinath, Fremont, CA (US)

(21) Appl. No.: 19/165,078

(22) PCT Filed: Mar. 18, 2024
(86) PCT No.: PCT/US2024/020468

§ 371 Date: Sep. 12, 2025

Related U.S. Application Data
(60) Provisional application No. 63/491,292, filed on Mar. 21, 2023.

(51) Int. Cl. C23C 16/455; C23C 16/44; H10B 41/20; H10B 43/20; H10P 14/40; H10P 14/43

(52) U.S. Cl. CPC C23C 16/45527; C23C 16/4408; C23C 16/45544; C23C 16/45557; H10P 14/412; H10P 14/43; H10B 41/20; H10B 43/20

(57) ABSTRACT

A method comprising providing a 3-D structure of a partially manufactured semiconductor substrate to a chamber, the 3-D structure comprising sidewalls, a plurality of openings in the sidewalls leading to a plurality of features having a plurality of interior regions fluidically accessible through the openings; and depositing a tungsten nucleation layer in the plurality of features using one or more deposition cycles, each deposition cycle comprising steps (a) to (c): (a) dosing diborane to the chamber two or more times without purging between the diborane dose; (b) after step (a), purging the chamber; and (c) after step (b), dosing tungsten hexafluoride to the chamber one or more times, wherein a purge is performed after each tungsten hexafluoride dose.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Deposition of materials including tungsten-containing materials is an integral part of many semiconductor fabrication processes. These materials may be used for horizontal interconnects, vias between adjacent metal layers, and contacts between metal layers and devices. As devices shrink and more complex patterning schemes are utilized in the industry, deposition of tungsten films becomes a challenge. The continued decrease in feature size and film thickness brings various challenges including high resistivity for thinner films and difficulty in obtaining void-free fill in features. Deposition in complex high aspect ratio structures such as 3D NAND structures is particularly challenging.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided herein are methods of forming tungsten (W) nucleation layers in features. The methods include atomic layer deposition (ALD) pulse sequences using tungsten hexafluoride (WF₆) as a reactant that result in low fluorine concentration in the deposited W nucleation layers.

One aspect of the disclosure relates to a method of depositing a tungsten nucleation layer in a 3-D structure. The method includes providing a 3-D structure of a partially manufactured semiconductor substrate to a chamber, the 3-D structure including sidewalls, a plurality of openings in the sidewalls leading to a plurality of features having a plurality of interior regions fluidically accessible through the openings; depositing a tungsten nucleation layer in the plurality of features using one or more deposition cycles, each deposition cycle including (a)-(c):
(a) dosing diborane to the chamber two or more times without purging between the diborane doses;
(b) after (a), purging the chamber; and
(c) after (b) dosing tungsten hexafluoride to the chamber one or more times, wherein a purge is performed after each tungsten hexafluoride dose.

In some embodiments, (c) includes at least 5, 10, or 15 tungsten hexafluoride doses. In some embodiments, the tungsten nucleation layer is deposited on a tungsten nitride film or tungsten carbonitride film in the plurality of features. In some embodiments, the tungsten nucleation layer is deposited on a titanium nitride film in the plurality of features. In some embodiments, the one or more deposition cycles are used to deposit the tungsten nucleation layer having a thickness of 10 to 30 Å. In some embodiments, (a) consists of 2, 3, or 4 doses of diborane.

In some embodiments, the fluorine concentration in the tungsten nucleation layer is no more than 1×10¹⁸ atoms/cm³. In some embodiments, the fluorine concentration in the tungsten nucleation layer is no more than 5×10¹⁷ atoms/cm³. In some embodiments, the fluorine concentration in the tungsten nucleation layer is no more than 1×10¹⁷ atoms/cm³.

In some embodiments, a substrate temperature is maintained at between 170° C. and 250° C. In some embodiments, chamber pressure between 3 and 10 Torr. In some embodiments, dose duration for at least one diborane dose in (a) is no more than 1 seconds. In some embodiments, dose duration for at least one diborane dose in (a) is less than 1 second. In some embodiments, dose duration for at least one tungsten hexafluoride dose in (c) is less than 2 seconds.

Another aspect of the disclosure relates to an apparatus including:
a process chamber including one or more showerheads in the process chamber to direct gases and one or more substrate supports;
a controller configured to execute machine-readable instructions for depositing a tungsten nucleation film using one or more deposition cycles, each deposition cycle including (a)-(c):
(a) causing dosing of diborane to the chamber two or more times without purging between the diborane doses;
(b) after (a), causing purging of the chamber; and
   (c) after (b), causing dosing of tungsten hexafluoride to the chamber one or more times, wherein a purge is performed after each tungsten hexafluoride dose.

These and other features of the disclosure are described further below with reference to the drawings.

### BRIEF DESCRIPTION OF DRAWINGS

FIGS. 1A-1E present different views and aspects of an example 3-D NAND structure.

FIG. 2 presents a schematic representation of a feature having a conformal nucleation layer.

FIGS. 3A and 3B present examples of pulse sequences that may be employed during nucleation layer deposition.

FIG. 4 shows a schematic example of a method of filling a 3D-NAND structure with metal.

FIGS. 5-7 shows schematic representations of apparatuses that may be used to perform the methods described herein.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Provided herein are methods of forming metal nucleation layers in features. In particular embodiments, the methods are used to fill wordline features in 3D NAND structures. However, the methods may also be used for metal layer formation in other features including vias and other vertically-oriented features. In some embodiments, the methods are used for tungsten (W) feature fill.

The methods described herein are performed on a substrate that may be housed in a chamber. The substrate may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon.

Substrates may have features such as via or contact holes, which may be characterized by one or more of narrow and/or re-entrant openings, constrictions within the feature, and high aspect ratios. A feature may be formed in one or more of the above-described layers. For example, the feature may be formed at least partially in a dielectric layer. In some embodiments, a feature may have an aspect ratio of at least about 2:1, at least about 4:1, at least about 6:1, at least about 10:1, at least about 25:1, or higher. One example of a feature is a hole or via in a semiconductor substrate or a layer on the substrate.

For some metallization schemes, an adhesion layer and/or barrier layer may be formed to line a feature prior to filling it with metal. A diffusion barrier is a layer that prevents diffusion of species between layers. An adhesion layer is a layer that promotes adhesion of a layer to an underlying layer.

For certain tungsten metallization applications, tungsten nitride (WN) diffusion barriers may be used. WN barriers have several advantages over barriers such as a titanium adhesion/titanium nitride barrier (Ti/TiN) bilayers. These include the ability to conformally deposit thin WN layers and the ability to deposit WN directly on dielectrics without an adhesion layer. These advantages allow more of the space available to be filled with W, lowering the overall contact resistance. Further, deposition of a WN layer can be performed at much lower temperatures than Ti/TiN, making it advantageous for low thermal budget applications.

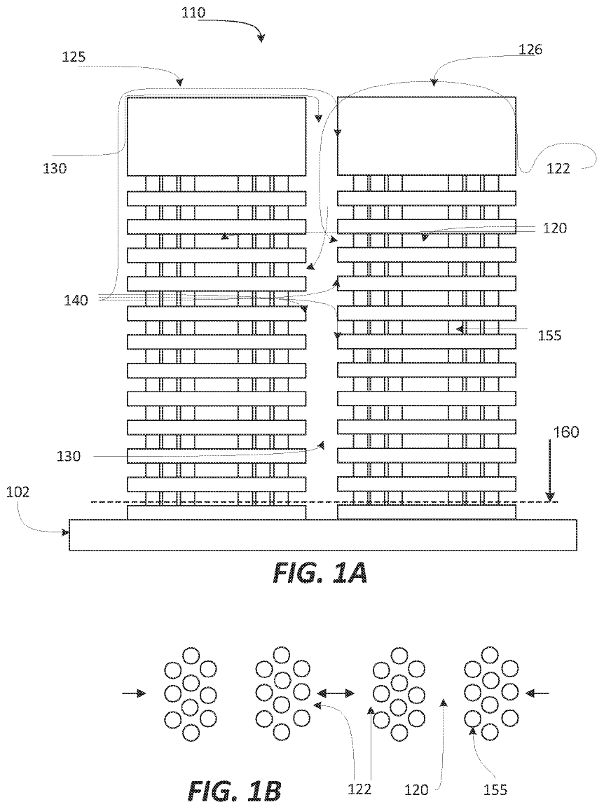

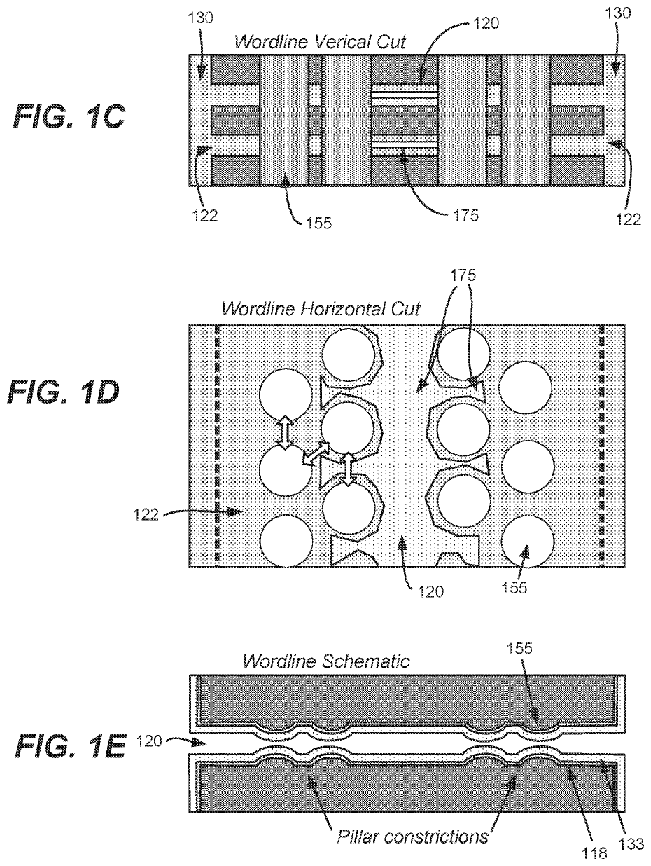

In some embodiments, the methods are used to deposit W nucleation layers on WN or TiN barrier layers. The methods may be used for wordline fill in 3-D NAND structures. FIG. 1A presents a cross-sectional side-view of a 3-D NAND structure 110 (formed on a silicon or other semiconductor substrate 102) having VNAND stacks (left 125 and right 126), central vertical structure 130, and a plurality of stacked horizontal wordline features 120 with openings 122 on opposite sidewalls 140 of central vertical structure 130. Note that FIG. 1A displays two stacks of the exhibited 3-D NAND structure 110, which together form the trench-like central vertical structure 130. There may be more than two such stacks arranged in sequence and running spatially parallel to one another with the gap between each adjacent pair of stacks forming a central vertical structure 130, like that illustrated in FIG. 1A. The horizontal wordline features 120 are 3-D memory wordline features that are fluidically accessible from the central vertical structure 130 through the openings 122. The horizontal wordline features 120 present in both the 3-D NAND stacks 125 and 126 shown in FIG. 1A (i.e., the left 3-D NAND stack 125 and the right 3-D NAND stack 126) are also accessible from the other sides of the stacks (far left and far right, respectively) through similar vertical structures formed by additional 3-D NAND stacks (to the far left and far right, but not shown). In other words, each 3-D NAND stack 125, 126 contains a stack of wordline features that are fluidically accessible from both sides of the b 3-D NAND stack through a central vertical structure 130. In the particular example schematically illustrated in FIG. 1A, each 3-D NAND stack contains 6 pairs of stacked wordlines; however, in other embodiments, a 3-D NAND memory layout may contain any number of vertically stacked pairs of wordlines.

The wordline features in a 3-D NAND stack may be formed by depositing an alternating stack of silicon oxide and silicon nitride layers, and then selectively removing the nitride layers leaving a stack of oxide layers having gaps between them. These gaps are the wordline features. Any number of wordlines may be vertically stacked in such a 3-D NAND structure so long as there is a technique for forming them available, as well as a technique available to successfully accomplish (substantially) void-free fills of the vertical features. Thus, for example, a 3-D NAND stack may include between 2 and 512 horizontal wordline features, or between 2 and 256 horizontal wordline features, or between 8 and 128 horizontal wordline features, or between 16 and 64 horizontal wordline features, and so forth (the listed ranges understood to include the recited end points).

FIG. 1B presents a cross-sectional top-down view of the same 3-D NAND structure 110 shown in side-view in FIG. 1A with the cross-section taken through the horizontal section 160 as indicated by the dashed horizontal line in FIG. 1A. The cross-section of FIG. 1B illustrates several rows of pillars 155, which run vertically from the base of semiconductor substrate 102 to the top of 3-D NAND structure 110. In some embodiments, these pillars 155 are formed from a polysilicon material. Polysilicon pillars may serve as gate electrodes for stacked memory cells formed within the pillars. The top-view of FIG. 1B illustrates that the pillars 155 form constrictions in the openings 122 to wordline features 120—i.e. fluidic accessibility of wordline features 120 from the central vertical structure 130 via openings 122 (as indicated by the arrows in FIG. 1G) is inhibited by pillars 155. This reduction in fluidic accessibility increases the difficulty of uniformly filling wordline features 120 with material. The structure of wordline features 120 and the challenge of uniformly filling them with material due to the presence of pillars 155 is further illustrated in FIGS. 1C, 1D, and 1E.

FIG. 1C exhibits a vertical cut through a 3-D NAND structure similar to that shown in FIG. 1A, but here focused on a single pair of wordline features 120. FIG. 1C also schematically illustrates a void 175 in the filled wordline features 120. FIG. 1D also schematically illustrates void 175, but in this figure illustrated via a horizontal cut through pillars 155, similar to the horizontal cut exhibited in FIG. 1G. FIG. 1E illustrates the accumulation of tungsten 133 or other metal around the constriction-forming pillars 155, the accumulation resulting in the pinch-off of openings 122, so that no additional metal can be deposited in the region of voids 175. Also shown in FIG. 1E is a barrier layer 118 on which the tungsten layer, including the nucleation and bulk layer, may be deposited.

Apparent from FIGS. 1C and 1D is that void-free wordline fill relies on migration of sufficient quantities of deposition precursor down through vertical structure 130, through openings 122, past the constricting pillars 155, and into the furthest reaches of wordline features 120, prior to the accumulated deposition of metal around pillars 155 causing a pinch-off of the openings 122 and preventing further precursor migration into wordline features 120. Similarly, FIG. 1E exhibits a single wordline feature 120 viewed cross-sectionally from above and illustrates how a generally conformal deposition of material begins to pinch-off the interior of wordline feature 120 because the significant width of pillars 155 acts to partially block, and/or narrow, and/or constrict what would otherwise be an open path through wordline feature 120. (It should be noted that the example in FIG. 1E can be understood as a 2-D rendering of the 3-D features of the structure of the pillar constrictions shown in FIG. 1D, thus illustrating constrictions that would be seen in a plan view rather than in a cross-sectional view.)

The challenges due to reduced fluidic accessibility increase as 3D NAND structure become more complex. In some embodiments, for example, reactants may diffuse past at least 5, at least 10, at least 15, at least 20, at least 25, or at least 30 pillars to reach the innermost wordline feature. With an increasing number of pillars, the opportunity for non-uniform deposition occurs.

Another challenge in tungsten wordline fill is preventing fluorine incorporation in the film and underlying dielectric. Tungsten hexafluoride (WF₆) is a useful precursor as it is a gas at standard conditions, unlike many tungsten halide compounds. However, its use in typical tungsten deposition results in unacceptably high levels of fluorine. Described below are methods of depositing tungsten nucleation layers using WF₆ that result in tungsten nucleation layers having good continuity with very low levels of fluorine. Subsequent processing to fill the feature with tungsten can also employ WF₆.

Examples of deposition in horizontally-oriented and vertically-oriented features are described herein. It should be noted that in at least most cases, the examples are applicable to both horizontally-oriented and vertically-oriented features. Moreover, it should also be noted that in the description below, the term “vertical” may be used to refer to a direction generally orthogonal to the plane of the substrate and the term “lateral” or “horizontal” to refer to a direction generally parallel to the plane of the substrate.

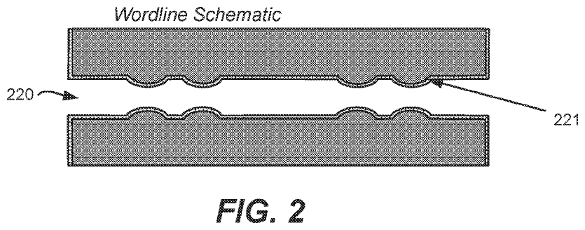

FIG. 2 depicts a schematic example of a wordline feature 220 in a 3D NAND structure. In FIG. 2, a 2-D rendering of 3-D features of a partially-fabricated 3D NAND structure prior to tungsten fill, is shown including the wordline feature 220 and a conformal tungsten nucleation layer 221. The pillar constrictions are shown in the figure representing constrictions that would be seen in a plan rather than cross-sectional view. The conformal tungsten nucleation layer 221 may be deposited on a barrier layer such as a titanium nitride (TiN) or tungsten nitride (WN) (not shown). The barrier layer may be deposited on a dielectric layer (not shown) such an aluminum oxide or other dielectric. In some embodiments, the nucleation layer may be deposited directly on a dielectric layer without an intervening barrier layer.

For conformal deposition of a tungsten nucleation layer, an atomic layer deposition (ALD) sequence may be used. Such a sequence can employ the following operations: (i) providing a layer of reducing agent on a substrate surface, and (ii) contacting the substrate surface with a tungsten-containing precursor to form a tungsten layer on the substrate. Each of these operations can involve delivering a dose of a reactant (reducing agent, tungsten-containing precursor) to a chamber housing a substrate including the feature. Purges are performed between these doses to purge out the reactants from the chamber.

Diborane (B₂H₆) may be used as a reducing agent in the methods described herein. B2H6 is an effective reducing agent, however, it thermally decomposes relative easily to boron and hydrogen. Because of the complexity and long diffusion lengths of the structure, it can be challenging to deliver diborane throughout the structure with minimal decomposition. Thermal decomposition results in non-uniformity with diborane decomposing at the first available surface without diffusing through the structure. In the methods described herein, multiple sequential diborane doses may be used without intervening purges. Charge volumes may be used to deliver the doses.

With a high volume, multiple dose delivery of diborane, the diborane can diffuse through the entire 3D NAND structure with minimal decomposition. Chamber pressure and substrate temperature may also be controlled to mitigate thermal decomposition. Pressure may be between 3 and 10 Torr and temperature may be between 170° C. and 250° C. according to various embodiments.

After the diborane is delivered, a purge is performed. This is followed by one or more doses of the tungsten-containing precursor, each of which is followed by a purge operation.

For a diborane (B₂H₆) reducing agent and tungsten hexafluoride (WF₆) or other tungsten-containing precursor, and a sequence can be expressed as Bₓ/purge/(W/purge)_{y} with B representing a B₂H₆ dose and W representing a WF₆ dose. This sequence can be repeated for multiple cycles to deposit a W nucleation layer. In the expression “x” is an integer of 2 or more, e.g., 2, 3, or 4, and y is an integer of 1 or more. The Bₓ/purge/(W/purge)_{y} sequence itself can be repeated one or more times to deposit the nucleation layer.

In some embodiments, y (the number of tungsten-containing precursor pulses in each cycle of the nucleation layer sequence) is at least 2, or at least 3. By using multiple short doses, it can minimize byproduct production. The subsequent purge removes the generated byproducts before they build up. This can allow the adsorbed reducing agent to be completely converted.

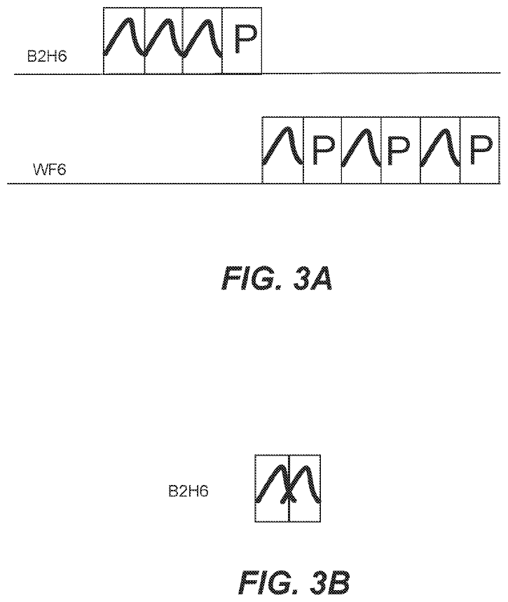

FIG. 3A shows an example of a sequence for tungsten nucleation deposition. In the example Bₓ/purge/(W/purge)_{y} sequence, x=3 and y=3. Each dose is represented by a peaked line representing the increase and decrease in mass flow of diborane or tungsten hexafluoride into the chamber. This is due to using a charge volume. Gas is held in a charge volume at a high pressure (e.g. 400 Torr to 1000 Torr). At the beginning of the dose, gas is allowed to flow from the charge volume to the chamber, resulting in a rapid decrease in pressure in the charge volume. The decrease in pressure of the charge volume corresponds with an increased mass flow of gas into the chamber. As the pressure in the charge volume decreases, the mass flow of gas into the chamber will also decrease. In the example of FIG. 3A, purge operations are represented by a capital P. However, the purge gas may also be delivered from a charge volume as described above.

In FIG. 3A, three consecutive diborane doses are shown, followed by a purge. According to various embodiments, the diborane doses may be of the same or different lengths. For example, multiple 0.5 or 1 second doses may be used. In some embodiments, the number of charge volumes may affect the dose time. For example, if two charge volumes are allotted for the diborane doses, using three doses may involve a longer second dose as the first charge volume is charged. In one example, a dose sequence of 0.5s/2.5s/0.5s (where s is seconds) may be used. With sufficient charge volumes, multiple doses of the same duration can be used. Dose duration may be up to 5 seconds, though shorter pulses may be useful to avoid decomposition. In some embodiments, each dose duration is no more than 2 seconds or 1 second. In some embodiments, it may be less than 1 second.

In FIG. 3A, the diborane doses are shown as non-overlapping. However, the diborane doses may overlap as illustrated in FIG. 3B, which shows two consecutive, overlapping diborane doses. Examples of the number of diborane pulses may be 2 to 5, e.g., 2, 3, or 4. In some embodiments, a single short diborane dose may be sufficient.

According to various embodiments, diborane may be provided with a nitrogen carrier gas (e.g., 5%/95% B₂H₆/N₂). Argon may be used to further dilute the diborane, e.g., 1:1 Ar:(B₂H₆/N₂) or 2:1(B₂H₆/N₂). In some embodiments, diborane may be co-flowed with hydrogen (H₂). Hydrogen may be used as parameter to control diborane exposure profile. Diborane decomposes more slowly in the presence of hydrogen than in another carrier gas such as nitrogen (N₂). For complex structures in which the diborane treatment reaches further into the structure, hydrogen may be added. For example, in some 3D NAND structures with multiple pillars, hydrogen may be added to allow the diborane to pass one or more pillars without thermal decomposition.

Returning to FIG. 3A, a purge is performed after the final diborane dose and after each tungsten hexafluoride dose. The number of tungsten hexafluoride doses in each sequence may be significantly more than 3—for example, it may be 5, 9, 15, 20, 25 etc. In some embodiments, it is at least 3, 5, 9, or 15. Dose time may be less than 5 seconds, less than 2 seconds, or less than 1 second. In some embodiments, for example, it may be 0.25 seconds, 0.5 seconds, or 0.75 seconds. Purge time is also short, e.g., less than 2 seconds. In some embodiments, it is one second.

Both step coverage and fluorine concentration of the tungsten nucleation layer are improved using multiple short doses of diborane and tungsten hexafluoride as compared to fewer, longer doses. This is illustrated in the below table which shows step coverage and fluorine concentration for various nucleation layer pulse sequences. The top BBW row is an example of using few longer sequences, with an example pulse time of 5 or more seconds. The middle and last rows use a 0.5s/2.5s/0.5s pulse duration for the boron doses and a 0.25s dose duration for the tungsten hexafluoride doses.

| | | Nucleation | Nucleation |
|---|---|---|---|
| Nucleation Layer | | Layer Step | Layer F |
| Sequence | Pressure/Temp | Coverage | content |
| BBW | 250 C., 10 Torr | 83% | 1.4E18 |
| Bₓ/purge/(W/purge)_{y} | 225 C., 5 Torr | 95% | 5.0E16 |
| sequence x = 3, y = 15 (no | | | |
| purge between B doses) | | | |
| Bₓ/purge/(W/purge)_{y} | 225 C., 10 Torr | 97% | 1.1E17 |
| sequence x = 3, y = 15 (no | | | |
| purge between B doses) | | | |

Resistivity is also improved significantly. For example, for a 100 Å (bulk+nucleation layer of about 18 Å) film, resistivity for a nucleation layer deposited using a BW (diborane/purge/tungsten hexafluoride/purge) sequence with 5 second doses was about 30μΩ-cm. By contrast, resistivity 100 Å (bulk+nucleation layer of about 18 Å) film with the nucleation layer deposited using a Bₓ/purge/(W/purge)_{y} sequence with significantly shorter doses was 26μΩ-cm.

A Bₓ/purge/(W/purge)_{y} sequence can be repeated to deposit a nucleation layer. Example total nucleation layer thicknesses range from 10 Å to 30 Å.

After depositing a nucleation layer, bulk deposition may be performed to deposit a bulk layer on the nucleation layer. Bulk deposition can occur by an ALD or CVD process. In a CVD process, a reducing agent and a metal precursor are co-flowed into a deposition chamber to deposit a bulk fill layer in the feature. An inert carrier gas may be used to deliver one or more of the reactant streams, which may or may not be pre-mixed. This operation generally involves flowing the reactants continuously until the desired amount is deposited. In certain implementations, the CVD operation may take place in multiple stages, with multiple periods of continuous and simultaneous flow of reactants separated by periods of one or more reactant flows diverted.

For conformal deposition and deposition into complex structures such as 3D NAND structures, ALD deposition of a bulk layer may be used. ALD deposition of a bulk layer involves exposure to alternating pulses of a metal-containing precursor and a reducing agent, separated by an inert purge gas, using the metal precursors described above with reference to nucleation layer deposition. The same or different metal precursor used in nucleation layer deposition may be used for bulk deposition. In contrast to nucleation layer deposition in which a strong reducing agent such as diborane or silane may be used, hydrogen is often the reducing agent for bulk deposition.

Deposition may proceed according to various implementations until a certain feature profile is achieved and/or a certain amount of metal is deposited. In some implementations, the deposition time and other relevant parameters may be determined by modeling and/or trial and error. In some implementations, a process chamber may be equipped with various sensors to perform in-situ metrology measurements for end-point detection of a deposition operation. Examples of in-situ metrology include optical microscopy and X-Ray Fluorescence (XRF) for determining thickness of deposited films.

In some embodiments, the conformal tungsten layer may be characterized as low resistivity and, in some embodiments, low stress and/or low fluorine. Because the wordline features are unfilled (with the exception of the nucleation layer), a relatively fast deposition technique may be used. In some embodiments, this involves alternating pulses of a W-containing precursor, such as WF₆) and hydrogen (H₂), or other reducing agent, to deposit the first tungsten layer in an ALD process. Purge operations may separate the pulses. Relatively short pulse times may be used for deposition to increase throughput.

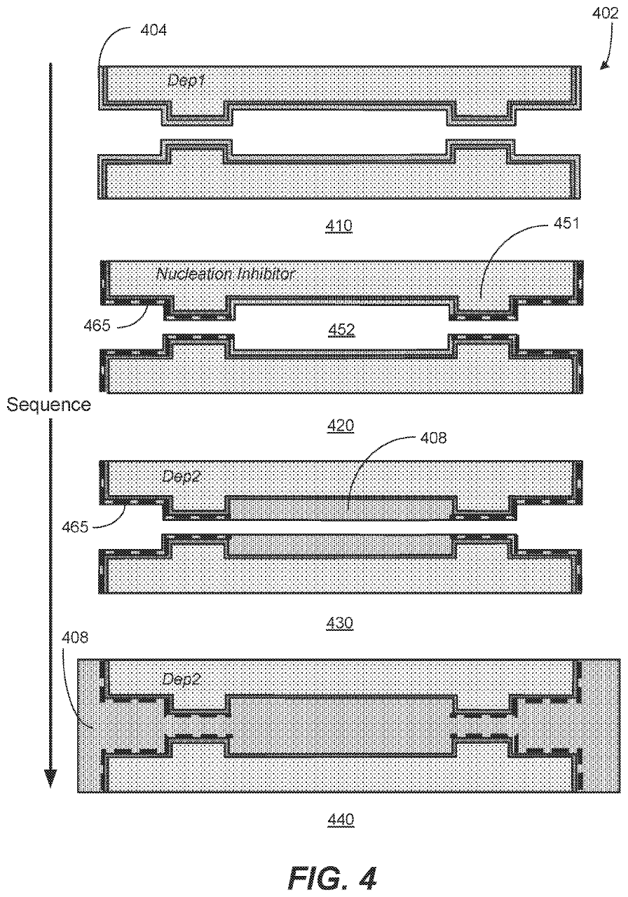

In some embodiments, deposition process may involve one or more inhibition operations. FIG. 4 shows a deposition-inhibition-deposition (DID) sequence for a wordline in 3D NAND structure. At 410, the wordline feature 402 is shown after a conformal deposition of a layer of metal 404. Deposition of the layer of metal 404 includes deposition of a nucleation layer as described above and may further include a bulk deposition process. At 420, the feature 402 is shown after an inhibition treatment. The treated surfaces 465 extend through the constriction formed by the pillars 451. In this example, the treated surfaces 465 through pillar 451 constrictions are inhibited while the surfaces of the interior at 452 are not inhibited. Thus, in the example of FIG. 4, the inhibition treatment is laterally non-conformal. However, the treatment may be uniform in a vertical direction such that each wordline is inhibited at approximately the same areas.

At 430, a process is performed to selectively deposit metal in accordance with the inhibition profile: bulk metal 408 is preferentially deposited on the non-inhibited portions of the metal layer 404, such that hard-to-fill regions behind constrictions are filled. At 440, the bulk deposition continues, filling the remainder of the feature with bulk metal 408.

In some embodiments, the nucleation processes described above may be used to deposit nucleation layers of other metals. In such embodiments, metal-containing precursors are reacted with diborane. Examples of other metal-containing precursors are provided below. Other metal-containing precursors may also be used for subsequent bulk deposition. For example, molybdenum-containing precursors may be used for molybdenum word lines, etc.

### Metal-containing Precursors

As described above, WF6 may be used to deposit a W nucleation layer. WF₆ is a useful precursor as it is in the gas phase at deposition conditions. For deposition of W bulk layers, WF₆ may also be used. In some embodiments, other tungsten-containing precursors may be suitable for performing disclosed embodiments. For example, a metal-organic tungsten-containing precursor may be used. Organo-metallic precursors and precursors that are free of fluorine, such as MDNOW (methylcyclopentadienyl-dicarbonylnitrosyl-tungsten) and EDNOW (ethylcyclopentadienyl-dicarbonylnitrosyl-tungsten) may also be used. Chlorine-containing tungsten precursors (WClₓ) such as tungsten pentachloride (WCl₅) and tungsten hexachloride (WCl₆) may be used.

Deposition of other metals may be performed. These include molybdenum, ruthenium, and cobalt. To deposit molybdenum (Mo), Mo-containing precursors including molybdenum hexafluoride (MoF₆), molybdenum pentachloride (MoCl₅), molybdenum dichloride dioxide (MoO₂Cl₂), molybdenum tetrachloride oxide (MoOCl₄), and molybdenum hexacarbonyl (Mo(CO)₆) may be used.

To deposit ruthenium (Ru), Ru-precursors may be used. Examples of ruthenium precursors that may be used for oxidative reactions include (ethylbenzyl)(1-ethyl-1,4-cyclohexadienyl)Ru(0), (1-isopropyl-4-methylbenzyl)(1,3-cyclohexadienyl)Ru(0), 2,3-dimethyl-1,3-butadienyl)Ru(0)tricarbonyl, (1,3-cyclohexadienyl)Ru(0)tricarbonyl, and (cyclopentadienyl)(ethyl)Ru(II)dicarbonyl. Examples of ruthenium precursors that react with non-oxidizing reactants are bis(5-methyl-2,4-hexanediketonato)Ru(II)dicarbonyl and bis(ethylcyclopentadienyl)Ru(II).

To deposit cobalt (Co), cobalt-containing precursors including dicarbonyl cyclopentadienyl cobalt (I), cobalt carbonyl, various cobalt amidinate precursors, cobalt diazadienyl complexes, cobalt amidinate/guanidinate precursors, and combinations thereof may be used.

The metal-containing precursor may be reacted with a reducing agent as described above. Diborane may be used as the nucleation layer reducing agent. In some embodiments, H2 is used as a reducing agent for bulk layer deposition to deposit high purity films.

As described above, bulk deposition may be performed across a wafer. In some implementations, bulk deposition can occur by a CVD process in which a reducing agent and a metal-containing precursor are flowed into a deposition chamber to deposit a bulk fill layer in the feature. An inert carrier gas may be used to deliver one or more of the reactant streams, which may or may not be pre-mixed. Unlike PNL or ALD processes, this operation generally involves flowing the reactants continuously until the desired amount is deposited. In certain implementations, the CVD operation may take place in multiple stages, with multiple periods of continuous and simultaneous flow of reactants separated by periods of one or more reactant flows diverted. Bulk deposition may also be performed using ALD processes in which a metal-containing precursor is alternated with a reducing agent such as H₂. In some implementations, ALD may be used to deposit an initial bulk layer in a Dep1 process with CVD used for the remaining feature fill after inhibition. In some implementations, ALD may be used for feature fill with CVD used for an overburden layer. In some implementations, ALD may be used for all of the bulk layer deposition.

The metal films described herein may include some amount of other compounds, dopants and/or impurities such as nitrogen, carbon, oxygen, boron, phosphorous, sulfur, silicon, germanium and the like, depending on the particular precursors and processes used. The metal content in the film may range from 20% to 100% (atomic) metal. In many implementations, the films are metal-rich, having at least 50% (atomic) metal, or even at least about 60%, 75%, 90%, or 99% (atomic) metal. In some implementations, the films may be a mixture of metallic or elemental metal (e.g., W, Mo, Co, or Ru) and other metal-containing compounds such as tungsten carbide (WC), tungsten nitride (WN), molybdenum nitride (MoN) etc. CVD and ALD deposition of these materials can include using any appropriate precursors as described above.

For feature fill, an inhibition process may be used after deposition of a nucleation layer. Plasma inhibition processes involve exposure to a plasma generated from a nitrogen containing compound, such as N₂. Plasma power, chamber pressure, and/or process gases may be pulsed in some embodiments. Thermal inhibition processes generally involve exposing the feature to a nitrogen-containing compound such as ammonia (NH₃) or hydrazine (N₂H₄) to non-conformally inhibit the feature near the feature opening. In some embodiments, the thermal inhibition processes are performed at temperatures ranging from 250° C. to 450° C. At these temperatures, exposure of a previously formed tungsten or other layer to NH₃ results in an inhibition effect. Other potentially inhibiting chemistries such as nitrogen (N₂) or hydrogen (H₂) may be used for thermal inhibition at higher temperatures (e.g., 900° C.). For many applications, however, these high temperatures exceed the thermal budget. In addition to ammonia, other hydrogen-containing nitriding agents such as hydrazine may be used at lower temperatures appropriate for back end of line (BEOL) applications. During thermal inhibition, a metal precursor may be flowed with the inhibition gas or in alternating pulses with the gas.

Nitridation of a surface can passivate it. Subsequent deposition of tungsten or other metal such as molybdenum or cobalt on a nitrided surface is significantly delayed, compared to on a regular bulk tungsten film. In addition to NF₃, fluorocarbons such as CF₄ or C₂F₈ may be used. However, in certain implementations, the inhibition species are fluorine-free to prevent etching during inhibition.

In addition to the surfaces described above, nucleation may be inhibited on liner/barrier layers surfaces such as TiN and/or WN surfaces. Any chemistry that passivates these surfaces may be used. Inhibition chemistry can also be used to tune an inhibition profile, with different ratios of active inhibiting species used. For example, for inhibition of W surfaces, nitrogen may have a stronger inhibiting effect than hydrogen; adjusting the ratio of N₂ and H₂ gas in a forming gas can be used to tune a profile.

In certain implementations, the substrate can be heated up or cooled down before inhibition. A predetermined temperature for the substrate can be selected to induce a chemical reaction between the feature surface and inhibition species and/or promote adsorption of the inhibition species, as well as to control the rate of the reaction or adsorption. For example, a temperature may be selected to have high reaction rate such that more inhibition occurs near the gas source.

### Apparatus

Any suitable chamber may be used to implement the disclosed embodiments. Example deposition apparatuses include various systems, e.g., ALTUS® and ALTUS® Max, available from Lam Research Corp., of Fremont, California, or any of a variety of other commercially available processing systems.

In some embodiments, a first deposition may be performed at a first station that is one of two, five, or even more deposition stations positioned within a single deposition chamber. Thus, for example, diborane and tungsten hexafluoride may be introduced as described above to deposit a nucleation layer to the surface of the semiconductor substrate, at the first station, using an individual gas supply system that creates a localized atmosphere at the substrate surface. The same or another station may be used for deposition of a conformal layer using ALD. A third station may be used for an inhibition treatment, followed by another bulk deposition operation.

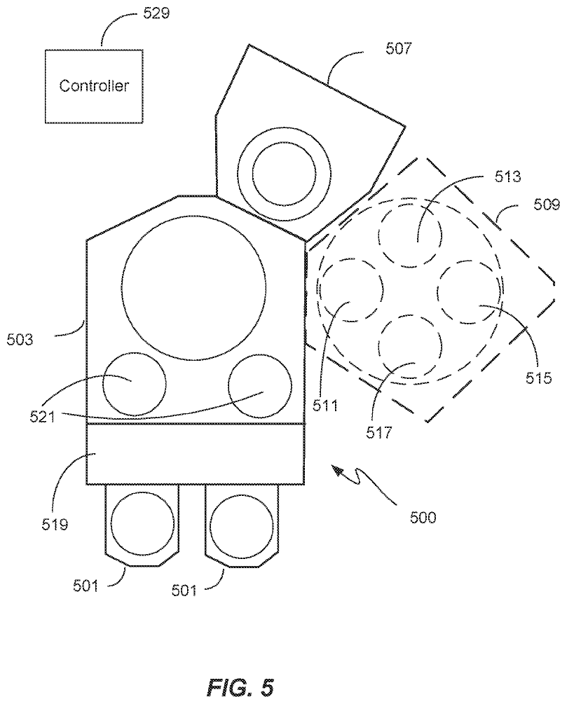

FIG. 5 is a schematic of a process system suitable for conducting deposition processes in accordance with embodiments. The system 500 includes a transfer module 503. The transfer module 503 provides a clean, pressurized environment to minimize risk of contamination of substrates being processed as they are moved between various reactor modules. Mounted on the transfer module 503 is a multi-station reactor 509 capable of performing ALD deposition of W nucleation layers and/or other metal films, inhibition operations, and CVD according to various embodiments. Multi-station reactor 509 may include multiple stations 511, 513, 515, and 517 that may sequentially perform operations in accordance with disclosed embodiments. For example, multi-station reactor 509 may be configured such that station 511 performs a W nucleation layer deposition using a WF₆ and B₂H₆, station 513 performs ALD tungsten bulk deposition of a conformal layer using H₂ as reducing agent, station 515 performs a nitridation using NH₃, and station 517 may perform a bulk ALD fill after treatment using H₂ ae reducing agent. In another example, station 511 may perform deposition of WN layer, station 513 performs ALD deposition of a conformal layer including a nucleation layer, station 515 performs a NF₃ treatment operation, and station 517 may perform a bulk ALD fill after treatment using H₂ ae reducing agent. Stations may include a heated pedestal or substrate support, one or more gas inlets or showerhead or dispersion plate.

Returning to FIG. 5, also mounted on the transfer module 503 may be one or more single or multi-station modules 507 capable of performing plasma or chemical (non-plasma) pre-cleans, other deposition operations, or etch operations. The module may also be used for various treatments to, for example, prepare a substrate for a deposition process. The system 500 also includes one or more wafer source modules 501, where wafers are stored before and after processing. An atmospheric robot (not shown) in the atmospheric transfer chamber 519 may first remove wafers from the source modules 501 to loadlocks 521. A wafer transfer device (generally a robot arm unit) in the transfer module 503 moves the wafers from loadlocks 521 to and among the modules mounted on the transfer module 503.

In various embodiments, a system controller 529 is employed to control process conditions during deposition. The controller 529 will typically include one or more memory devices and one or more processors. A processor may include a CPU or computer, analog and/or digital input/output connections, stepper motor controller boards, etc.

The controller 529 may control all of the activities of the deposition apparatus. The system controller 529 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 529 may be employed in some embodiments.

Typically, there will be a user interface associated with the controller 529. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 529. The signals for controlling the process are output on the analog and digital output connections of the deposition apparatus 500.

The system software may be designed or configured in many different ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller 529 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 529, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 529, in some implementations, may be a part of or coupled to a computer that is integrated with, coupled to the system, otherwise networked to the system, or a combination thereof. For example, the controller 529 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. The parameters may be specific to the type of process to be performed and the type of tool that the controller is configured to interface with or control. As described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 529 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

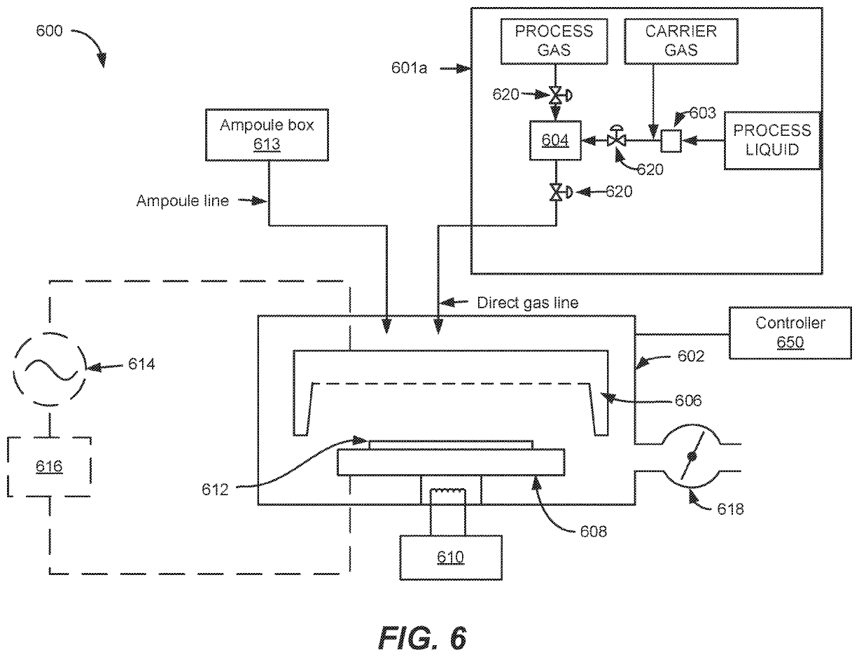

FIG. 6 depicts a schematic illustration of an embodiment of a process station 600 having a process chamber 602 for maintaining a low-pressure environment. In some embodiments, a plurality of process stations may be included in a common low-pressure process tool environment. For example, FIG. 5 depicts an embodiment of a multi-station reactor 509. In some embodiments, one or more hardware parameters of process station 600, including those discussed in detail below, may be adjusted programmatically by one or more computer controllers 650. In some other embodiments, a process chamber may be a single station chamber.

Process station 600 fluidly communicates with reactant delivery system 601a for delivering process gases to a distribution showerhead 606. Reactant delivery system 601a includes a mixing vessel 604 for blending and/or conditioning process gases, such as a metal precursor-containing gas, a hydrogen-containing gas, an inhibition gas, an argon or other carrier gas, or other reactant-containing gas, for delivery to showerhead 606. One or more mixing vessel inlet valves 620 may control introduction of process gases to mixing vessel 604.

As an example, the embodiment of FIG. 6 includes a vaporization point 603 for vaporizing liquid reactant to be supplied to the mixing vessel 604. In some embodiments, vaporization point 603 may be a heated vaporizer. In some embodiments, a liquid precursor or liquid reactant may be vaporized at a liquid injector (not shown). For example, a liquid injector may inject pulses of a liquid reactant into a carrier gas stream upstream of the mixing vessel 604. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 603. In one scenario, a liquid injector may be mounted directly to mixing vessel 604. In another scenario, a liquid injector may be mounted directly to showerhead 606.

In some embodiments, a liquid flow controller (LFC) upstream of vaporization point 603 may be provided for controlling a mass flow of liquid for vaporization and delivery to process chamber 602. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller. According to various embodiments, one or more charge volumes may be connected to the process gas supplies.

In some embodiments, a solid precursor may be supplied in an ampoule box 613 from which precursor may be delivered to

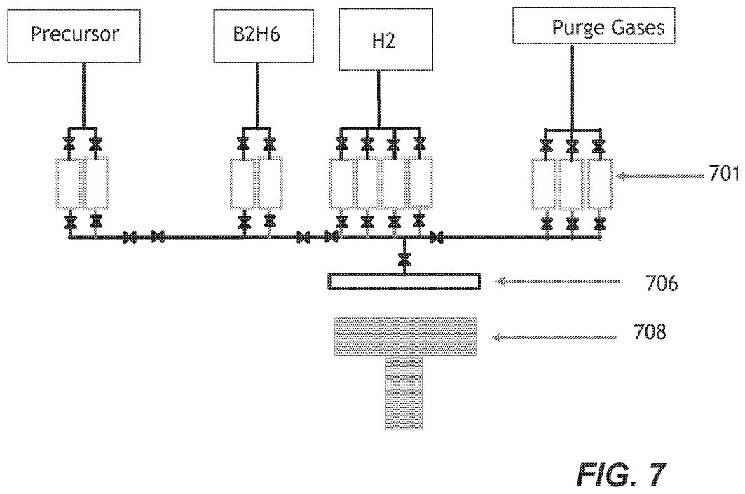

In some embodiments, the station may be equipped with one or more charge volumes. Pulsing the reactant, purge, and/or inhibition gases may involve a charge volume. An example apparatus is shown in FIG. 7, in which four gas sources (precursor, B₂H₆, H₂, and purge gases) are each connected to charge volumes 701. According to various embodiments, all or only subset of these gas sources may be connected to charge volumes. The charge volumes 701 are used to build a pressurized volume of gas, which is then flowed into the process chamber. Gas from charge volumes 701 is pressurized (e.g., to 300 Torr- 700 Torr) and enters a chamber via showerhead 706. A pedestal 708 for supporting a wafer is also shown.

Returning to FIG. 6, showerhead 606 distributes process gases toward substrate 612. In the embodiment shown in FIG. 16, the substrate 612 is located beneath showerhead 606 and is shown resting on a pedestal 608. Showerhead 606 may have any suitable shape and may have any suitable number and arrangement of ports for distributing process gases to substrate 612.

In some embodiments, pedestal 608 may be raised or lowered to expose substrate 612 to a volume between the substrate 612 and the showerhead 606. In some embodiments, pedestal 608 may be temperature controlled via heater 610. Pedestal 608 may be set to any suitable temperature during operations for performing various disclosed embodiments. It will be appreciated that, in some embodiments, pedestal height may be adjusted programmatically by a suitable computer controller 650. At the conclusion of a process phase, pedestal 608 may be lowered during another substrate transfer phase to allow removal of substrate 612 from pedestal 608.

In some embodiments, a position of showerhead 606 may be adjusted relative to pedestal 608 to vary a volume between the substrate 612 and the showerhead 606. Further, it will be appreciated that a vertical position of pedestal 608 and/or showerhead 606 may be varied by any suitable mechanism within the scope of the present disclosure. In some embodiments, pedestal 608 may include a rotational axis for rotating an orientation of substrate 612. In some embodiments, one or more of these example adjustments may be performed programmatically by one or more suitable computer controllers 650. The computer controller 650 may include any of the features described below with respect to controller 650 of FIG. 6.

If plasma is used during deposition or inhibition, showerhead 606 and pedestal 608 electrically communicate with a radio frequency (RF) power supply 614 and matching network 616 for powering a plasma. In some embodiments, the plasma energy may be controlled by controlling one or more of a process station pressure, a gas concentration, an RF source power, an RF source frequency, and a plasma power pulse timing. For example, RF power supply 614 and matching network 616 may be operated at any suitable power to form a plasma having a desired composition of radical species. Likewise, RF power supply 614 may provide RF power of any suitable frequency. In some embodiments, RF power supply 614 may be configured to control high-and low-frequency RF power sources independently of one another. Example low-frequency RF frequencies may include, but are not limited to, frequencies between 0 kHz and 900 kHz. Example high-frequency RF frequencies may include, but are not limited to, frequencies between 1.8 MHz and 2.45 GHz, or greater than about 13.56 MHz, or greater than 27 MHz, or greater than 80 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 650 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of an inert and/or a reactant gas (e.g., a metal precursor), instructions for setting a flow rate of a carrier gas (such as argon), and time delay instructions for the first recipe phase. A second, subsequent recipe phase may include instructions for modulating or stopping a flow rate of an inert and/or a reactant gas, and instructions for modulating a flow rate of a carrier or purge gas and time delay instructions for the second recipe phase. A third recipe phase may include instructions for modulating a flow rate of H₂, instructions for modulating the flow rate of a carrier or purge gas and time delay instructions for the third recipe phase. A fourth, subsequent recipe phase may include instructions for modulating or stopping a flow rate of an inert and/or a reactant gas, and instructions for modulating a flow rate of a carrier or purge gas and time delay instructions for the fourth recipe phase. It will be appreciated that these recipe phases may be further subdivided and/or iterated in any suitable way within the scope of the present disclosure.

Further, in some embodiments, pressure control for process station 600 may be provided by butterfly valve 618. As shown in the embodiment of FIG. 6, butterfly valve 618 throttles a vacuum provided by a downstream vacuum pump (not shown). However, in some embodiments, pressure control of process station 600 may also be adjusted by varying a flow rate of one or more gases introduced to the process station 600.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

Unless otherwise stated, ranges in this disclosure are inclusive of the endpoints. For example, between 170° C. and 250° C.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### Conclusion

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method comprising:
providing a 3-D structure of a partially manufactured semiconductor substrate to a chamber, the 3-D structure comprising sidewalls, a plurality of openings in the sidewalls leading to a plurality of features having a plurality of interior regions fluidically accessible through the openings;
depositing a tungsten nucleation layer in the plurality of features using one or more deposition cycles, each deposition cycle comprising (a)-(c):
(a) dosing diborane to the chamber two or more times without purging between the diborane doses;
(b) after (a), purging the chamber; and
(c) after (b) dosing tungsten hexafluoride to the chamber one or more times, wherein a purge is performed after each tungsten hexafluoride dose.

2. The method of claim 1, wherein (c) comprises at least 5 tungsten hexafluoride doses.

3. The method of claim 1, wherein (c) comprises at least 10 tungsten hexafluoride doses.

4. The method of claim 1, wherein (c) comprises at least 15 tungsten hexafluoride doses.

5. The method of claim 1, wherein the tungsten nucleation layer is deposited on a tungsten nitride film or tungsten carbonitride film in the plurality of features.

6. The method of claim 1, wherein the tungsten nucleation layer is deposited on a titanium nitride film in the plurality of features.

7. The method of claim 1, wherein the one or more deposition cycles are used to deposit the tungsten nucleation layer having a thickness of 10 to 30 Å.

8. The method of claim 1, wherein (a) consists of 2, 3, or 4 doses of diborane.

9. The method of claim 1, wherein the fluorine concentration in the tungsten nucleation layer is no more than 1×10¹⁸ atoms/cm³.

10. The method of claim 1, wherein the fluorine concentration in the tungsten nucleation layer is no more than 5×10¹⁷ atoms/cm³.

11. The method of claim 1, wherein the fluorine concentration in the tungsten nucleation layer is no more than 1×10¹⁷ atoms/cm³.

12. The method of claim 1, wherein a substrate temperature is maintained at between 170° C. and 250° C. .

13. The method of claim 1, wherein chamber pressure between 3 and 10 Torr.

14. The method of claim 1, wherein dose duration for at least one diborane dose in (a) is no more than 1 seconds.

15. The method of claim 1, wherein dose duration for at least one diborane dose in (a) is less than 1 second.

16. The method of claim 1, wherein dose duration for at least one tungsten hexafluoride dose in (c) is less than 2 seconds.

17. An apparatus comprising:
a process chamber comprising one or more showerheads in the process chamber to direct gases and one or more substrate supports;
a controller configured to execute machine-readable instructions for depositing a tungsten nucleation film using one or more deposition cycles, each deposition cycle comprising (a)-(c):
(a) causing dosing of diborane to the chamber two or more times without purging between the diborane doses;
(b) after (a), causing purging of the chamber; and
(c) after (b), causing dosing of tungsten hexafluoride to the chamber one or more times, wherein a purge is performed after each tungsten hexafluoride dose.
